(19) United States
(12) Patent Application Publication
(10) Pub. No.: US 2016/0133691 A1
(43) Pub. Date: May 12, 2016

(54) DRAM MIMCAP Stack with MoO2 Electrode

(71) Applicant: Intermolecular, Inc., San Jose, CA (US)

(72) Inventors: Prashant B. Phatak, San Jose, CA (US); Hanhong Chen, Milpitas, CA (US); Tony P. Chiang, Campbell, CA (US); Chien-Lan Hsueh, Campbell, CA (US); Monica Mathur, San Jose, CA (US)

(21) Appl. No.: 14/534,816

(22) Filed: Nov. 6, 2014

(51) Int. Cl. H01L 49/02; H01L 27/108

(52) U.S. Cl. CPC H01L 28/75; H01L 27/108

(57) ABSTRACT

Steps are taken to ensure that the bulk dielectric layer exhibits a crystalline phase before the deposition of a second electrode layer. The crystalline phase of the bulk dielectric layer facilitates the crystallization of the second electrode layer at lower temperature during a subsequent anneal treatment. In some embodiments, one or more interface layers are inserted between the bulk dielectric layer and the first electrode layer and/or the second electrode layer. The interface layers may act as an oxygen sink, facilitate the crystallization of the electrode layer at lower temperature during a subsequent anneal treatment, or provide barriers to leakage current through the film stack.

### FIELD OF THE DISCLOSURE

The present invention generally relates to the field of dynamic random access memory (DRAM), and more particularly to dielectric material processing for improved DRAM performance.

### BACKGROUND OF THE DISCLOSURE

Dynamic Random Access Memory utilizes capacitors to store bits of information within an integrated circuit. A capacitor is formed by placing a dielectric material between two electrodes formed from conductive materials. A capacitor's ability to hold electrical charge (i.e., capacitance) is a function of the surface area of the capacitor plates A, the distance between the capacitor plates d (i.e. the physical thickness of the dielectric layer), and the relative dielectric constant or k-value of the dielectric material. The capacitance is given by:

$$C = κ {ɛ}_{o} \frac{A}{d} \qquad ( Eqn . 1 )$$

where ∈ₒ represents the vacuum permittivity.

The dielectric constant is a measure of a material's polarizability. Therefore, the higher the dielectric constant of a material, the more charge the capacitor can hold. Therefore, if the k-value of the dielectric is increased, the area of the capacitor can be decreased and maintain the desired cell capacitance. Reducing the size of capacitors within the device is important for the miniaturization of integrated circuits. This allows the packing of millions (mega-bit (Mb)) or billions (giga-bit (Gb)) of memory cells into a single semiconductor device. The goal is to maintain a large cell capacitance (generally ˜10 to 25 fF) and a low leakage current (generally <10⁻⁷ A cm⁻²). The physical thickness of the dielectric layers in DRAM capacitors could not be reduced unlimitedly in order to avoid leakage current caused by tunneling mechanisms which exponentially increases as the thickness of the dielectric layer decreases.

Traditionally, SiO₂ has been used as the dielectric material and semiconducting materials (semiconductor-insulator-semiconductor [SIS] cell designs) have been used as the electrodes. The cell capacitance was maintained by increasing the area of the capacitor using very complex capacitor morphologies while also decreasing the thickness of the SiO₂ dielectric layer. Increases of the leakage current above the desired specifications have demanded the development of new capacitor geometries, new electrode materials, and new dielectric materials. Cell designs have migrated to metal-insulator-semiconductor (MIS) and now to metal-insulator-metal (MIM) cell designs for higher performance.

One class of high-k dielectric materials possessing the characteristics required for implementation in advanced DRAM capacitors are high-k metal oxide materials. Examples of suitable dielectric materials comprise Al₂O₃, HfO₂, HfSiOₓ, ZrO₂, Ta₂O₅, TiO₂, Nb₂O₅, SrTiO₃ (STO), BaSrTiOₓ (BST), PbZrTiOₓ (PZT), etc. TiO₂ and ZrO₂ are two specific examples of metal oxide dielectric materials which display significant promise in terms of serving as a high-k dielectric material for implementation in DRAM capacitors.

Typically, DRAM devices at technology nodes of 80 nm and below use MIM capacitors wherein the electrode materials are metals. These electrode materials generally have higher conductivities than the semiconductor electrode materials, higher work functions, exhibit improved stability over the semiconductor electrode materials, and exhibit reduced depletion effects. The electrode materials must have high conductivity to ensure fast device speeds. Representative examples of electrode materials for MIM capacitors are metals, conductive metal oxides, conductive metal silicides, conductive metal nitrides (i.e. TiN), or combinations thereof. MIM capacitors in these DRAM applications utilize insulating materials having a dielectric constant, or k-value, significantly higher than that of SiO₂ (k=3.9). For DRAM capacitors, the goal is to utilize dielectric materials with k values greater than about 40. Such materials are generally classified as high-k materials. Representative examples of high-k materials for MIM capacitors are non-conducting metal oxides, non-conducting metal nitrides, non-conducting metal silicates or combinations thereof. These dielectrics may also include additional dopant materials.

A figure of merit in DRAM technology is the electrical performance of the dielectric material as compared to SiO₂ known as the Equivalent Oxide Thickness (EOT). A high-k material's EOT is calculated using a normalized measure of silicon dioxide (SiO₂ k=3.9) as a reference, given by:

$$E O T = \frac{3.9}{κ} \cdot d \qquad ( Eqn . 2 )$$

where d represents the physical thickness of the capacitor dielectric.

As DRAM technologies scale below the 40 nm technology node, manufacturers must reduce the EOT of the high-k dielectric films in MIM capacitors in order to increase charge storage capacity. The goal is to utilize dielectric materials that exhibit an EOT of less than about 0.8 nm while maintaining a physical thickness of about 5-20 nm.

Generally, as the dielectric constant of a material increases, the band gap of the material decreases. For example. The rutile phase of TiO₂ has a k-value of about 80 and a band gap of about 3.0 eV while ZrO₂ in the tetragonal phase has a k-value of about 43 and a band gap of about 5.8 eV. The low band gap may lead to high leakage current in the device. As a result, without the utilization of countervailing measures, capacitor stacks implementing high-k dielectric materials may experience large leakage currents. High work function electrodes (e.g., electrodes having a work function of greater than 5.0 eV) may be utilized in order to counter the effects of implementing a reduced band gap high-k dielectric layer within the DRAM capacitor. Metals, such as platinum, gold, ruthenium, and ruthenium oxide are examples of high work function electrode materials suitable for inhibiting device leakage in a DRAM capacitor having a high-k dielectric layer. The noble metal systems, however, are prohibitively expensive when employed in a mass production context. Moreover, electrodes fabricated from noble metals often suffer from poor manufacturing qualities, such as surface roughness, poor adhesion, and form a contamination risk in the fab. Therefore, there is a need to develop non-noble electrode materials for use in DRAM capacitors.

### SUMMARY OF THE DISCLOSURE

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

In some embodiments, steps are taken to ensure that the bulk dielectric layer exhibits a crystalline phase before the deposition of a second electrode layer. The crystalline phase of the bulk dielectric layer facilitates the crystallization of the second electrode layer at lower temperature during a subsequent anneal treatment. In some embodiments, one or more interface layers are inserted between the bulk dielectric layer and the first electrode layer and/or the second electrode layer. The interface layers may act as an oxygen sink, facilitate the crystallization of the electrode layer at lower temperature during a subsequent anneal treatment, or provide barriers to leakage current through the film stack.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a simplified cross-sectional view of a DRAM capacitor stack fabricated in accordance with some embodiments.

FIG. 2 provides a table of exemplary film stacks in accordance with some embodiments.

FIG. 3 illustrates a simplified cross-sectional view of a DRAM memory cell fabricated in accordance with some embodiments.

FIG. 4 provides a table of exemplary film stacks in accordance with some embodiments.

FIG. 5 illustrates a simplified cross-sectional view of a DRAM memory cell fabricated in accordance with some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

It must be noted that as used herein and in the claims, the singular forms “a,” “an,” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. Where the modifier “about” or “approximately” is used, the stated quantity can vary by up to 10%.

As used herein, the term “substantially” generally refers to ±5% of a stated value.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

As used herein, a material (e.g. a dielectric material or an electrode material) will be considered to be “crystalline” if it exhibits greater than or equal to 30 volume % crystallinity as measured by a technique such as x-ray diffraction (XRD).

The term “substrate” as used herein may refer to any workpiece on which formation or treatment of material layers is desired. Non-limiting examples include silicon, germanium, silica, sapphire, zinc oxide, silicon carbide, aluminum nitride, gallium nitride, Spinel, silicon on oxide, silicon carbide on oxide, glass, gallium nitride, indium nitride, aluminum nitride, glasses, combinations or alloys thereof, and other solid materials.

As used herein, the notation “Mo—O” and “MoO” and “MoOₓ” will be understood to be equivalent and will be used interchangeably and will be understood to include a material containing these elements in any ratio. Where a specific composition is discussed, the atomic concentrations (or ranges) will be provided. The notation is extendable to other materials and other elemental combinations (e.g. Mo—O—N, MoON, MoONₓ, etc.) discussed herein.

As used herein, the terms “film” and “layer” will be understood to represent a portion of a stack. They will be understood to cover both a single layer as well as a multilayered structure (i.e. a nanolaminate). As used herein, these terms will be used synonymously and will be considered equivalent.

As used herein, the term “between” (when used with a range of values) will be understood to mean that both boundary values and any value between the boundaries can be within the scope of the range.

As used herein, the terms “first,” “second,” and other ordinals will be understood to provide differentiation only, rather than imposing any specific spatial or temporal order.

As used herein, the term “oxide” (of an element) will be understood to include additional components besides the element and oxygen, including but not limited to a dopant or alloy.

As used herein, the term “nitride” (of an element) will be understood to include additional components besides the element and nitrogen, including but not limited to a dopant or alloy.

Dopants can be added to the dielectric material to increase the k-value and/or decrease the leakage current. As used herein, the dopant may be electrically active or not electrically active. The definition excludes residues and impurities such as carbon, etc. that may be present in the material due to inefficiencies of the process or impurities in the precursor materials. The concentration of the dopant is one factor that affects the crystallinity of the dielectric material. Other factors that affect the crystallinity of the dielectric material comprise annealing time, annealing temperature, film thickness, etc. Generally, as the concentration of the dopant is increased, the crystallization temperature of the dielectric material increases.

Dopants can be added to the electrode material to alter the resistivity and/or influence the crystallinity. As used herein, the dopant may be electrically active or not electrically active. The definition excludes residues and impurities such as carbon, etc. that may be present in the material due to inefficiencies of the process or impurities in the precursor materials. The concentration of the dopant is one factor that affects the crystallinity of the dielectric material. Other factors that affect the crystallinity of the electrode material comprise annealing time, annealing temperature, film thickness, etc.

The term “nanolaminate”, as used herein, will be understood to be defined as a material or layer that is formed from the deposition of a plurality of sub-layers. Typically, the sub-layers include different materials and the different sub-layers are alternated in a predetermined ratio of thicknesses and/or compositions.

As used herein, the term “flash layer” will be understood to describe an additional layer inserted between the first (e.g. bottom) electrode layer and the dielectric layer.

As used herein, the term “capping layer” will be understood to describe an additional layer inserted between the second (e.g. top) electrode layer and the dielectric layer.

As used herein, the term “blocking layer” will be understood to describe an additional generic layer inserted either between the first (e.g. bottom) electrode layer and the dielectric layer, between the second (e.g. top) electrode layer and the dielectric layer, or both. As defined above, both “flash layers” and “capping layers” are examples of the more general “blocking layer”.

As used herein, the term “inert gas” will be understood to include noble gases (He, Ne, Ar, Kr, Xe) and, unless the text or context excludes it (e.g., by describing nitride formation as undesirable), nitrogen (N₂).

As used herein, the term “monolayer” will be understood to include a single layer of atoms or molecules covering a surface, with substantially all available bonding sites satisfied and substantially all individual members of the adsorbed species in direct physical contact with the underlying surface.

As used herein, the term “sub-monolayer” or “pre-wetting layer” will be understood to include a partial or incomplete monolayer; maximum thickness is one atom or molecule, but not all available bonding sites on the surface are covered, so that the average thickness is less than one atom or molecule.

As used herein, the term “surface” will be understood to describe the boundary between the ambient environment and a feature of the substrate.

As used herein, the term “seed” layer will be understood to describe a layer used to promote a desired crystallographic orientation of a subsequently deposited layer. Those skilled in the art will also understand that this concept is also known as “templating”.

DRAM capacitor stacks are formed from a number of deposited thin films.

Generally, a deposited thin film may be amorphous, crystalline, or a mixture thereof. Furthermore, several different crystalline phases may exist. Therefore, processes (both deposition and post-treatment) must be developed to maximize the formation of the desired composition and crystalline phase of the thin film. The thin films used to form the MIM DRAM capacitor stack may be formed using any common technique such as atomic layer deposition (ALD), plasma enhanced atomic layer deposition (PE-ALD), atomic vapor deposition (AVD), ultraviolet assisted atomic layer deposition (UV-ALD), chemical vapor deposition (CVD), plasma enhanced chemical vapor deposition (PECVD), or physical vapor deposition (PVD). Generally, because of the complex morphology of the DRAM capacitor structure, ALD, PE-ALD, AVD, or CVD are preferred methods of formation. However, any of these techniques are suitable for forming each of the various materials discussed below. Those skilled in the art will appreciate that the teachings described below are not limited by the technology used for the deposition process.

Leakage current in capacitor dielectric materials can be due to Schottky emission, Frenkel-Poole defects (e.g. oxygen vacancies (Vₒₓ) or grain boundaries), or Fowler-Nordheim tunneling. Schottky emission, also called thermionic emission, is a common mechanism and is the thermally activated flow of charge over an energy barrier whereby the effective barrier height of a MIM capacitor controls leakage current. The nominal barrier height is a function of the difference between the work function of the electrode and the electron affinity of the dielectric. The electron affinity of a dielectric is closely related to the conduction band offset of the dielectric. The Schottky emission behavior of a dielectric layer is generally determined by the properties of the dielectric/electrode interface. Frenkel-Poole emission allows the conduction of charges through a dielectric layer through the interaction with defect sites such as vacancies, grain boundaries, and the like. As such, the Frenkel-Poole emission behavior of a dielectric layer is generally determined by the dielectric layer's bulk properties. Fowler-Nordheim emission allows the conduction of charges through a dielectric layer through direct tunneling without any intermediary interaction with defects. As such, the Fowler-Nordheim emission behavior of a dielectric layer is generally determined by the physical thickness of the dielectric layer. This leakage current is a primary driving force in the adoption of high-k dielectric materials. The use of high-k materials allows the physical thickness of the dielectric layer to be as thick as possible while maintaining the required capacitance (see Eqn 1 above).

The mechanisms for charge transport discussed above suggest that there are several parameters that influence the leakage current across the electrode-dielectric interface. Examples of the parameters include physical thickness of the dielectric material, the band gap of the dielectric material, the work function of the electrode, the Schottky barrier height (SBH) between the electrode and the dielectric material, etc. The SBH has been found to be influenced by many variables such as the composition of the electrode and the dielectric, doping levels, defect densities, processing conditions, etc.

As discussed previously, conductive metal oxide materials such as molybdenum oxide are candidates for electrode materials due to their high work function values. Additionally, they have crystal structures that are generally complimentary to those of high k dielectric materials (e.g. the rutile phase of titanium oxide or the tetragonal phase of zirconium oxide). Transition metals such as molybdenum can exist in a number of valence states. As an example, the molybdenum in MoO₂ is in the +4 valence state and the molybdenum in MoO₃ is in the +6 valence state. For very thin molybdenum oxide films (i.e. < about 10 nm), it is difficult to precisely control the Mo:O atomic ratio. This leads to a higher resistance material which may not meet the resistivity and device speed requirements for future DRAM devices. Typically, molybdenum oxide is present as MoO₃ (or more generally MoO₂₊ₓ) after deposition. The film may be treated to convert the MoO₃ to conductive MoO₂. When used as the first (e.g. bottom) electrode in the capacitor stack, this treatment may include a thermal anneal treatment. This anneal treatment serves to convert the MoO₃ to MoO₂ and to crystallize the MoO₂ before the dielectric layer is deposited above the first electrode.

The integration of molybdenum oxide as a second electrode (e.g. top) layer has been difficult. The thermal treatments employed to the first electrode that convert the MoO₃ to MoO₂ and to crystallize the MoO₂ may have a negative impact on the performance of the underlying dielectric layer. Steps may be taken to lower the temperature of the anneal treatment required to convert the MoO₃ to MoO₂ and to crystallize the MoO₂ when molybdenum oxide is used as part of the second electrode.

In some embodiments, steps are taken to ensure that the underlying dielectric material is in a crystalline form before the deposition of the molybdenum oxide. In some embodiments, the dielectric material is titanium oxide (or doped titanium oxide) and this material is subjected to an anneal treatment to ensure that at least 30 volume % of the titanium oxide exhibits a rutile crystal structure before the molybdenum oxide is deposited. MoO₂ has a distorted rutile crystal structure. The underlying crystal structure of the titanium oxide may facilitate the conversion of the MoO₃ to MoO₂ at a lower temperature.

In some embodiments, steps are taken to ensure that the underlying dielectric material is in a crystalline form before the deposition of the molybdenum oxide. In some embodiments, the dielectric material is zirconium oxide (or doped zirconium oxide) and this material is subjected to an anneal treatment to ensure that at least 30 volume % of the zirconium oxide exhibits a tetragonal crystal structure before the molybdenum oxide is deposited. MoO₂ has a distorted rutile crystal structure. The underlying crystal structure of the zirconium oxide may facilitate the conversion of the MoO₃ to MoO₂ at a lower temperature.

Alternatively, an “oxygen sink” may be employed to scavenge the excess oxygen without impacting the underlying dielectric layer. In some embodiments, one or more interface layers are inserted between the dielectric layer(s) and molybdenum oxide second electrode to alter the crystallinity. Some materials that are attractive as interface layers for molybdenum oxide include elements from Group-4 (e.g. Ti, Zr, Hf) of the periodic table (using the new IUPAC designations). Another material that is attractive as an interface layer for molybdenum oxide includes aluminum oxide. These elements may be inserted as interface layers as either the metal oxide (e.g. titanium oxide) or as the metal nitride (e.g. titanium nitride).

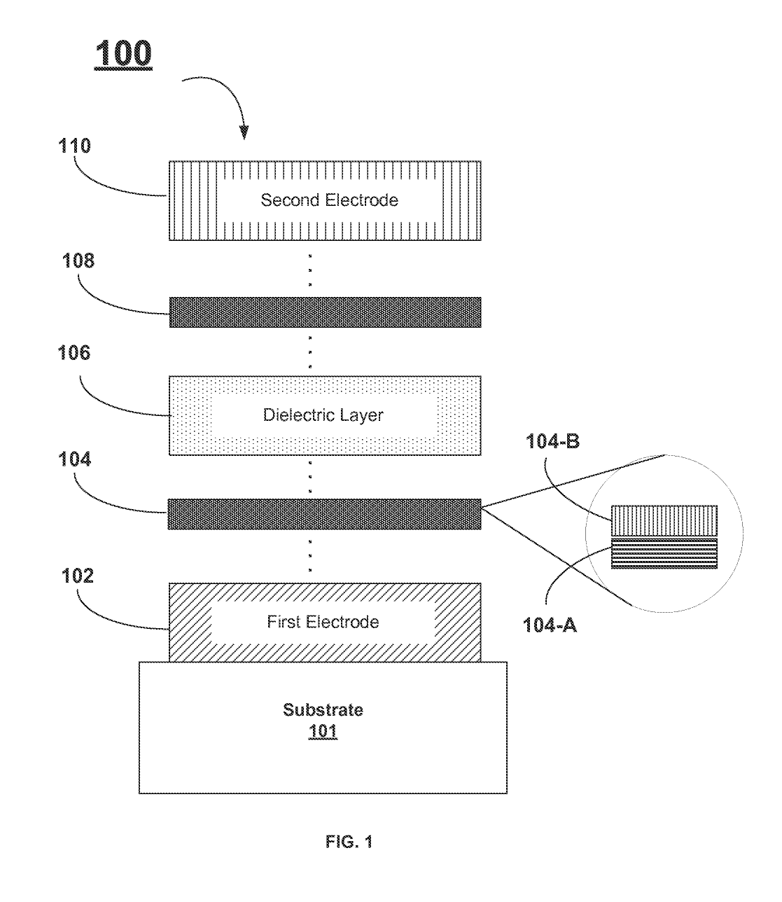

In FIGS. 1, 3, and 5, below, a capacitor stack is illustrated using a simple planar structure. Those skilled in the art will appreciate that the description and teachings to follow can be readily applied to any simple or complex capacitor morphology. The drawings are for illustrative purposes only and do not limit the application of the present invention.

FIG. 1 illustrates a simplified cross-sectional view of a DRAM capacitor stack fabricated in accordance with some embodiments. First electrode layer, 102, is formed above substrate, 101. Generally, the substrate has already received several processing steps in the manufacture of a full DRAM device. First electrode layer, 102, includes at least one of metals, metal alloys, conductive metal oxides, conductive metal nitrides, conductive metal silicides, etc. One class of materials that is of particular interest is the conductive metal oxides. Specific metal oxide materials of interest include molybdenum oxide, tungsten oxide, ruthenium oxide, iridium oxide, chromium oxide, manganese oxide, tin oxide, cobalt oxide, or nickel oxide. Additional candidates for the second electrode material include titanium nitride, nickel, titanium aluminum nitride, platinum, iridium, palladium, cobalt, nickel nitride, tungsten nitride, vanadium nitride, molybdenum nitride, cobalt nitride, ruthenium, ruthenium nitride, nickel oxide, or combinations thereof. In some embodiments, first electrode, 102, includes multiple layers (not shown). As an example, a thicker titanium nitride layer (e.g. having a thickness between about 1 nm and about 4 nm) may be used as a current conductor and a thinner metal oxide layer (e.g. a molybdenum oxide layer having a thickness between about 0.2 nm and about 4 nm) may be used as a high work function layer and may also serve as a “seed” layer to promote a desired crystallographic orientation of a subsequently deposited dielectric layer. Optionally, first electrode, 102, can be annealed to crystallize the material.

First interface layer, 104, is formed above the first electrode. As mentioned previously, first interface layer, 104, is typically a material with a k value between about 10 and about 100 and is less than about 20 Angstroms in thickness. In some embodiments, first interface layer, 104, includes multiple layer. These may be illustrated in FIG. 1 as layers 104-A and 104-B. Examples of materials that would make suitable first interface layers include titanium nitride, titanium oxide, or combinations thereof. The purpose of the first interface layer(s) is to separate the molybdenum oxide layer from a subsequently deposited dielectric layer (e.g. zirconium oxide).

In the next step, bulk dielectric layer, 106, would then be formed above the first interface dielectric layer, 104. A wide variety of dielectric materials have been targeted for use in DRAM capacitors. Examples of suitable dielectric materials comprise Al₂O₃, BaSrTiOₓ (BST), HfO₂, HfSiOₓ, Nb₂O₅, PbZrTiOₓ (PZT), Ta₂O₅, TiO₂, SrTiO₃ (STO), ZrO₂, or doped versions of the same. The bulk dielectric layer is a different material from the first interface dielectric layer. These bulk dielectric materials may be formed as a single layer or may be formed as a hybrid or nanolaminate structure. In some embodiments, a specific dielectric material of interest is doped ZrO₂. Typically, Al is a common dopant used in ZrO₂ dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Ti, or Y. Typically, bulk dielectric layer, 106, is subjected to a post dielectric anneal (PDA) treatment before the formation of the next layer. The PDA treatment will crystallize the dielectric material.

Second interface layer, 108, is formed above the bulk dielectric layer. As mentioned previously, second interface layer, 108, is typically a material with a thickness of less than about 20 Angstroms. Examples of materials that would make suitable second interface layers include aluminum oxide, titanium nitride, titanium oxide, or combinations thereof. The purpose of the second interface layer(s) is to separate the zirconium oxide layer from a subsequently deposited high work function layer (e.g. molybdenum oxide).

In some embodiments, interface layers including aluminum oxide are inserted between the dielectric layer(s) and a second electrode material that includes molybdenum oxide. Without being limited by theory, it is believed that the aluminum oxide serves two purposes as an interface layer. Firstly, the aluminum oxide may serve as an “oxygen sink” and scavenge oxygen from the molybdenum oxide as it is converted from MoO₃ to MoO₂ during a subsequent anneal treatment. Secondly, the aluminum oxide layer may separate the zirconium oxide dielectric layer from the molybdenum oxide layer.

In some embodiments, interface layers including titanium oxide are inserted between the dielectric layer(s) and a second electrode material that includes molybdenum oxide. Without being limited by theory, it is believed that the titanium oxide serves two purposes as an interface layer. Firstly, the titanium oxide may serve as an “oxygen sink” and scavenge oxygen from the molybdenum oxide as it is converted from MoO₃ to MoO₂ during a subsequent anneal treatment. Secondly, the titanium oxide may exist in a rutile crystal structure. Molybdenum oxide may also exist as a distorted rutile crystal structure. Therefore, the titanium oxide may serve to promote the crystallization of the molybdenum oxide during subsequent anneal treatments. This may allow the molybdenum oxide to be crystallized at lower temperatures that will not negatively affect performance of the underlying dielectric materials. Finally, the titanium oxide layer may separate the zirconium oxide dielectric layer from the molybdenum oxide layer.

In some embodiments, interface layers including titanium nitride are inserted between the dielectric layer(s) and a second electrode material that includes molybdenum oxide. Without being limited by theory, it is believed that the titanium nitride serves two purposes as an interface layer. Firstly, the titanium nitride may serve as an “oxygen sink” and scavenge oxygen from the molybdenum oxide as it is converted from MoO₃ to MoO₂ during a subsequent anneal treatment. Secondly, the titanium nitride may exist in a cubic crystal structure. Molybdenum oxide may exist as a distorted rutile crystal structure. Therefore, the titanium nitride may serve to promote the crystallization of the molybdenum oxide during subsequent anneal treatments. This may allow the molybdenum oxide to be crystallized at lower temperatures that will not negatively affect performance of the underlying dielectric materials. Finally, the titanium nitride layer may separate the zirconium oxide dielectric layer from the molybdenum oxide layer.

The next step includes forming a second electrode layer, 110, above the second interface layer. The second electrode layer may be a metal, metal alloy, conductive metal oxide, conductive metal nitride, conductive metal silicide, or combinations thereof, etc. One class of materials that is of particular interest is the conductive metal oxides. Specific materials of interest comprise molybdenum oxide, tungsten oxide, ruthenium oxide, iridium oxide, chromium oxide, manganese oxide, tin oxide, cobalt oxide, or nickel oxide. Additional candidates for the second electrode material include titanium nitride, nickel, titanium aluminum nitride, platinum, iridium, palladium, cobalt, nickel nitride, tungsten nitride, vanadium nitride, molybdenum nitride, cobalt nitride, ruthenium, ruthenium nitride, nickel oxide, or combinations thereof.

In some embodiments, second electrode, 110, includes multiple layers (not shown). As an example, a thicker titanium nitride layer (e.g. having a thickness between about 1 nm and about 4 nm) may be used as a current conductor and a thinner metal oxide layer (e.g. a molybdenum oxide layer having a thickness between about 0.2 nm and about 4 nm) may be used as a high work function layer. Typically, the molybdenum oxide layer is disposed between the second interface layer, 108, and the titanium nitride layer in this configuration. Other examples of materials for use as the current conductor include titanium nitride, nickel, titanium aluminum nitride, platinum, iridium, palladium, cobalt, nickel nitride, tungsten nitride, vanadium nitride, molybdenum nitride, cobalt nitride, ruthenium, ruthenium nitride, nickel oxide, or combinations thereof. Other examples of metal oxide materials include tungsten oxide, ruthenium oxide, iridium oxide, chromium oxide, manganese oxide, tin oxide, cobalt oxide, or nickel oxide.

The remaining full DRAM device (not shown) would then be manufactured using well known techniques. Optionally, the DRAM capacitor stack may undergo a post metallization anneal (PMA) treatment. Examples of the PDA and PMA treatments described above are further described in U.S. patent application Ser. No. 13/159,842 (now U.S. Pat. No. 8,815,677) filed on Jun. 14, 2011, which is herein incorporated by reference for all purposes.

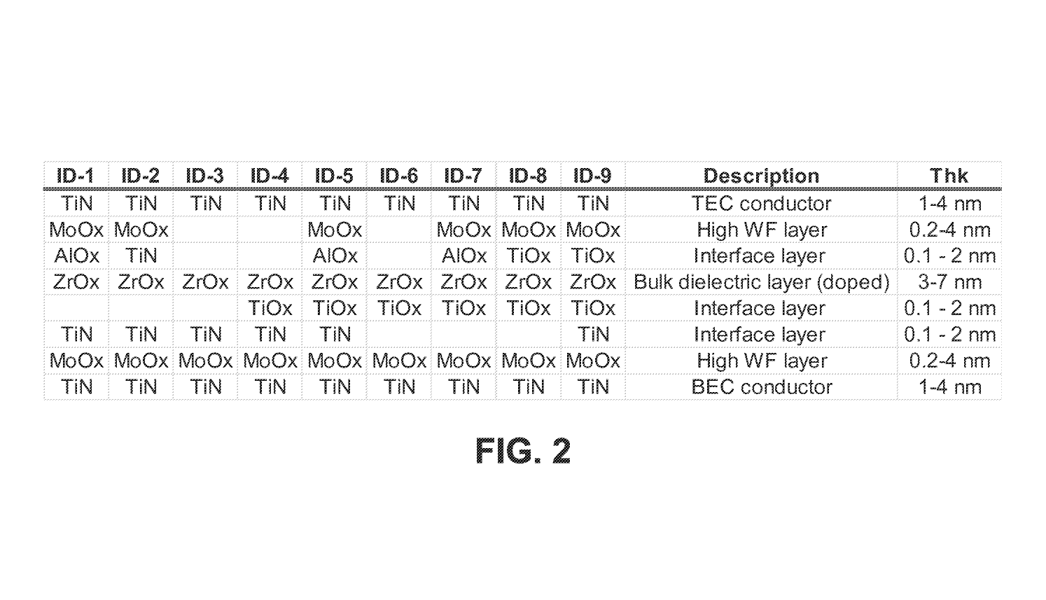

FIG. 2 provides a table of exemplary film stacks in accordance with some embodiments. FIG. 2 lists exemplary film stacks that may correspond to the description and illustration associated with FIG. 1. The nine stacks illustrated in FIG. 2 are simple examples and those skilled in the art will understand that other stacks can be envisioned based on the description associated with FIG. 1.

In some embodiments (ID-1), a first electrode layer, 102, includes a titanium nitride layer having a thickness between about 1 nm and about 4 nm and a molybdenum oxide layer having a thickness between about 0.2 nm and about 4 nm. Typically, the molybdenum oxide layer is formed above the titanium nitride layer. A first interface layer, 104, is formed above the first electrode layer and includes a titanium nitride layer having a thickness between about 0.1 nm and about 2 nm. A bulk dielectric layer, 106, is formed above the first interface layer and includes a zirconium oxide layer having a thickness between about 3 nm and about 7 nm. Typically, the bulk dielectric layer, 106 is doped. Typically, Al is a common dopant used in zirconium oxide dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Ti, or Y. A second interface layer, 108, is formed above the bulk dielectric layer and includes an aluminum oxide layer having a thickness between about 0.1 nm and about 2 nm. A second electrode layer, 110, is formed above the second interface layer and includes a titanium nitride layer having a thickness between about 1 nm and about 4 nm and a molybdenum oxide layer having a thickness between about 0.2 nm and about 4 nm. Typically, the titanium nitride layer is formed above the molybdenum oxide layer.

In some embodiments (ID-2), a first electrode layer, 102, includes a titanium nitride layer having a thickness between about 1 nm and about 4 nm and a molybdenum oxide layer having a thickness between about 0.2 nm and about 4 nm. Typically, the molybdenum oxide layer is formed above the titanium nitride layer. A first interface layer, 104, is formed above the first electrode layer and includes a titanium nitride layer having a thickness between about 0.1 nm and about 2 nm. A bulk dielectric layer, 106, is formed above the first interface layer and includes a zirconium oxide layer having a thickness between about 3 nm and about 7 nm. Typically, the bulk dielectric layer, 106 is doped. Typically, Al is a common dopant used in zirconium oxide dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Ti, or Y. A second interface layer, 108, is formed above the bulk dielectric layer and includes a titanium nitride layer having a thickness between about 0.1 nm and about 2 nm. A second electrode layer, 110, is formed above the second interface layer and includes a titanium nitride layer having a thickness between about 1 nm and about 4 nm and a molybdenum oxide layer having a thickness between about 0.2 nm and about 4 nm. Typically, the titanium nitride layer is formed above the molybdenum oxide layer.

In some embodiments (ID-3), a first electrode layer, 102, includes a titanium nitride layer having a thickness between about 1 nm and about 4 nm and a molybdenum oxide layer having a thickness between about 0.2 nm and about 4 nm. Typically, the molybdenum oxide layer is formed above the titanium nitride layer. A first interface layer, 104, is formed above the first electrode layer and includes a titanium nitride layer having a thickness between about 0.1 nm and about 2 nm. A bulk dielectric layer, 106, is formed above the first interface layer and includes a zirconium oxide layer having a thickness between about 3 nm and about 7 nm. Typically, the bulk dielectric layer, 106 is doped. Typically, Al is a common dopant used in zirconium oxide dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Ti, or Y. A second electrode layer, 110, is formed above the second interface layer and includes a titanium nitride layer having a thickness between about 1 nm and about 4.

In some embodiments (ID-4), a first electrode layer, 102, includes a titanium nitride layer having a thickness between about 1 nm and about 4 nm and a molybdenum oxide layer having a thickness between about 0.2 nm and about 4 nm. Typically, the molybdenum oxide layer is formed above the titanium nitride layer. A first interface layer, 104, is formed above the first electrode layer. First interface layer, 104, is a multilayer stack and includes a titanium nitride layer, 104-A, having a thickness between about 0.1 nm and about 2 nm and a titanium oxide layer, 104-B, having a thickness between about 0.1 nm and about 2 nm. A bulk dielectric layer, 106, is formed above the first interface layer(s) and includes a zirconium oxide layer having a thickness between about 3 nm and about 7 nm. Typically, the bulk dielectric layer, 106 is doped. Typically, Al is a common dopant used in zirconium oxide dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Ti, or Y. A second electrode layer, 110, is formed above the second interface layer and includes a titanium nitride layer having a thickness between about 1 nm and about 4.

In some embodiments (ID-5), a first electrode layer, 102, includes a titanium nitride layer having a thickness between about 1 nm and about 4 nm and a molybdenum oxide layer having a thickness between about 0.2 nm and about 4 nm. Typically, the molybdenum oxide layer is formed above the titanium nitride layer. A first interface layer, 104, is formed above the first electrode layer. First interface layer, 104, is a multilayer stack and includes a titanium nitride layer, 104-A, having a thickness between about 0.1 nm and about 2 nm and a titanium oxide layer, 104-B, having a thickness between about 0.1 nm and about 2 nm. A bulk dielectric layer, 106, is formed above the first interface layer(s) and includes a zirconium oxide layer having a thickness between about 3 nm and about 7 nm. Typically, the bulk dielectric layer, 106 is doped. Typically, Al is a common dopant used in zirconium oxide dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Ti, or Y. A second interface layer, 108, is formed above the bulk dielectric layer and includes an aluminum oxide layer having a thickness between about 0.1 nm and about 2 nm. A second electrode layer, 110, is formed above the second interface layer and includes a titanium nitride layer having a thickness between about 1 nm and about 4 nm and a molybdenum oxide layer having a thickness between about 0.2 nm and about 4 nm. Typically, the titanium nitride layer is formed above the molybdenum oxide layer.

In some embodiments (ID-6), a first electrode layer, 102, includes a titanium nitride layer having a thickness between about 1 nm and about 4 nm and a molybdenum oxide layer having a thickness between about 0.2 nm and about 4 nm. Typically, the molybdenum oxide layer is formed above the titanium nitride layer. A first interface layer, 104, is formed above the first electrode layer and includes a titanium oxide layer having a thickness between about 0.1 nm and about 2 nm. A bulk dielectric layer, 106, is formed above the first interface layer and includes a zirconium oxide layer having a thickness between about 3 nm and about 7 nm. Typically, the bulk dielectric layer, 106 is doped. Typically, Al is a common dopant used in zirconium oxide dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Ti, or Y. A second electrode layer, 110, is formed above the second interface layer and includes a titanium nitride layer having a thickness between about 1 nm and about 4.

In some embodiments (ID-7), a first electrode layer, 102, includes a titanium nitride layer having a thickness between about 1 nm and about 4 nm and a molybdenum oxide layer having a thickness between about 0.2 nm and about 4 nm. Typically, the molybdenum oxide layer is formed above the titanium nitride layer. A first interface layer, 104, is formed above the first electrode layer and includes a titanium oxide layer having a thickness between about 0.1 nm and about 2 nm. A bulk dielectric layer, 106, is formed above the first interface layer and includes a zirconium oxide layer having a thickness between about 3 nm and about 7 nm. Typically, the bulk dielectric layer, 106 is doped. Typically, Al is a common dopant used in zirconium oxide dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Ti, or Y. A second interface layer, 108, is formed above the bulk dielectric layer and includes an aluminum oxide layer having a thickness between about 0.1 nm and about 2 nm. A second electrode layer, 110, is formed above the second interface layer and includes a titanium nitride layer having a thickness between about 1 nm and about 4 nm and a molybdenum oxide layer having a thickness between about 0.2 nm and about 4 nm. Typically, the titanium nitride layer is formed above the molybdenum oxide layer.

In some embodiments (ID-8), a first electrode layer, 102, includes a titanium nitride layer having a thickness between about 1 nm and about 4 nm and a molybdenum oxide layer having a thickness between about 0.2 nm and about 4 nm. Typically, the molybdenum oxide layer is formed above the titanium nitride layer. A first interface layer, 104, is formed above the first electrode layer and includes a titanium oxide layer having a thickness between about 0.1 nm and about 2 nm. A bulk dielectric layer, 106, is formed above the first interface layer and includes a zirconium oxide layer having a thickness between about 3 nm and about 7 nm. Typically, the bulk dielectric layer, 106 is doped. Typically, Al is a common dopant used in zirconium oxide dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Ti, or Y. A second interface layer, 108, is formed above the bulk dielectric layer and includes a titanium oxide layer having a thickness between about 0.1 nm and about 2 nm. A second electrode layer, 110, is formed above the second interface layer and includes a titanium nitride layer having a thickness between about 1 nm and about 4 nm and a molybdenum oxide layer having a thickness between about 0.2 nm and about 4 nm. Typically, the titanium nitride layer is formed above the molybdenum oxide layer.

In some embodiments (ID-9), a first electrode layer, 102, includes a titanium nitride layer having a thickness between about 1 nm and about 4 nm and a molybdenum oxide layer having a thickness between about 0.2 nm and about 4 nm. Typically, the molybdenum oxide layer is formed above the titanium nitride layer. A first interface layer, 104, is formed above the first electrode layer. First interface layer, 104, is a multilayer stack and includes a titanium nitride layer, 104-A, having a thickness between about 0.1 nm and about 2 nm and a titanium oxide layer, 104-B, having a thickness between about 0.1 nm and about 2 nm. A bulk dielectric layer, 106, is formed above the first interface layer(s) and includes a zirconium oxide layer having a thickness between about 3 nm and about 7 nm. Typically, the bulk dielectric layer, 106 is doped. Typically, Al is a common dopant used in zirconium oxide dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Ti, or Y. A second interface layer, 108, is formed above the bulk dielectric layer and includes a titanium oxide layer having a thickness between about 0.1 nm and about 2 nm. A second electrode layer, 110, is formed above the second interface layer and includes a titanium nitride layer having a thickness between about 1 nm and about 4 nm and a molybdenum oxide layer having a thickness between about 0.2 nm and about 4 nm. Typically, the titanium nitride layer is formed above the molybdenum oxide layer.

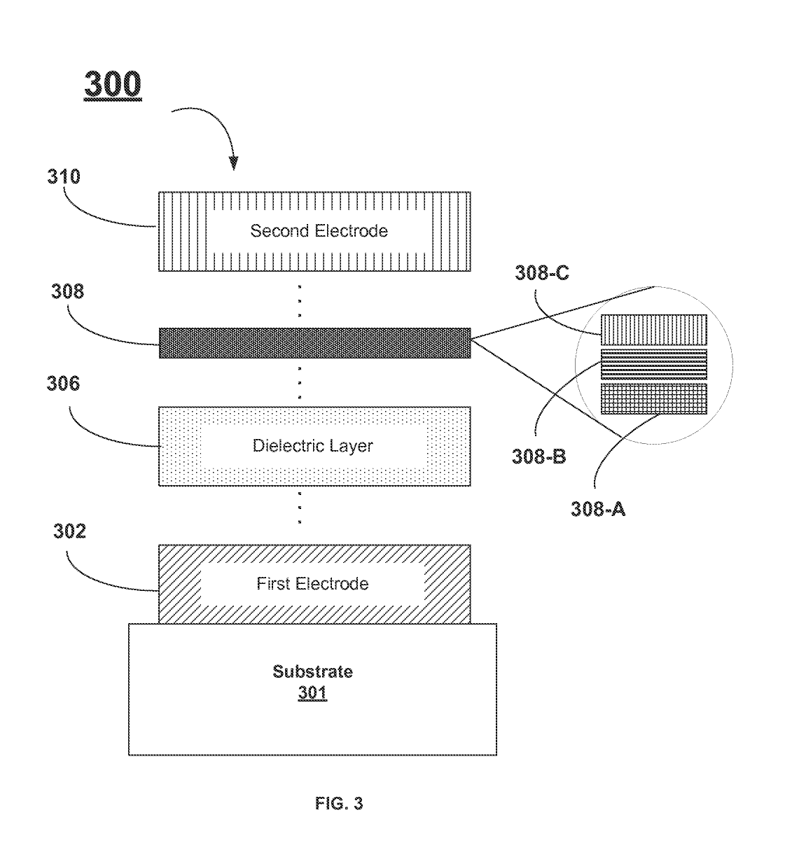

FIG. 3 illustrates a simplified cross-sectional view of a DRAM capacitor stack fabricated in accordance with some embodiments. First electrode layer, 302, is formed above substrate, 301. Generally, the substrate has already received several processing steps in the manufacture of a full DRAM device. First electrode layer, 302, includes at least one of metals, metal alloys, conductive metal oxides, conductive metal nitrides, conductive metal silicides, etc. One class of materials that is of particular interest is the conductive metal oxides. Specific metal oxide materials of interest include molybdenum oxide, tungsten oxide, ruthenium oxide, iridium oxide, chromium oxide, manganese oxide, tin oxide, cobalt oxide, or nickel oxide. Additional candidates for the second electrode material include titanium nitride, nickel, titanium aluminum nitride, platinum, iridium, palladium, cobalt, nickel nitride, tungsten nitride, vanadium nitride, molybdenum nitride, cobalt nitride, ruthenium, ruthenium nitride, nickel oxide, or combinations thereof. In some embodiments, first electrode, 302, includes multiple layers (not shown). As an example, a thicker titanium nitride layer (e.g. having a thickness between about 1 nm and about 4 nm) may be used as a current conductor and a thinner metal oxide layer (e.g. a molybdenum oxide layer having a thickness between about 0.2 nm and about 4 nm) may be used as a high work function layer and may also serve as a “seed” layer to promote a desired crystallographic orientation of a subsequently deposited dielectric layer. Optionally, first electrode, 302, can be annealed to crystallize the material.

In the next step, bulk dielectric layer, 306, would then be formed above the first electrode layer, 302. A wide variety of dielectric materials have been targeted for use in DRAM capacitors. Examples of suitable dielectric materials comprise Al₂O₃, BaSrTiOₓ (BST), HfO₂, HfSiOₓ, Nb₂O₅, PbZrTiOₓ (PZT), Ta₂O₅, TiO₂, SrTiO₃ (STO), ZrO₂, or doped versions of the same. These bulk dielectric materials may be formed as a single layer or may be formed as a hybrid or nanolaminate structure. In some embodiments, a specific dielectric material of interest is doped TiO₂. Typically, Al is a common dopant used in TiO₂ dielectrics to reduce the leakage current although many other dopants are also commonly used. A discussion of the doping of TiO₂ to reduce leakage current may be found in U.S. patent application. Ser. No. 13/219,870 filed on Aug. 29, 2011, and is herein incorporated by reference for all purposes. Dopants described therein comprise one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Y, or Zr. Typically, bulk dielectric layer, 306, is subjected to a post dielectric anneal (PDA) treatment before the formation of the next layer. The PDA treatment will crystallize the dielectric material.

Second interface layer, 308, is formed above the bulk dielectric layer. As mentioned previously, second interface layer, 308, is typically a material with a thickness of less than about 0.2 nm. Examples of materials that would make suitable second interface layers include aluminum oxide, titanium nitride, titanium oxide, zirconium oxide, or combinations thereof. In some embodiments, second interface layer, 308, includes multiple layers. These may be illustrated in FIG. 3 as layers 304-A, 304-B, and 304-C.

In some embodiments, interface layers including aluminum oxide are inserted between the dielectric layer(s) and a second electrode material that includes molybdenum oxide. Without being limited by theory, it is believed that the aluminum oxide serves two purposes as an interface layer. Firstly, the aluminum oxide may serve as an “oxygen sink” and scavenge oxygen from the molybdenum oxide as it is converted from MoO₃ to MoO₂ during a subsequent anneal treatment. Secondly, the aluminum oxide layer may separate the titanium oxide dielectric layer from the molybdenum oxide layer.

In some embodiments, interface layers including titanium oxide are inserted between the dielectric layer(s) and a second electrode material that includes molybdenum oxide. Without being limited by theory, it is believed that the titanium oxide serves two purposes as an interface layer. Firstly, the titanium oxide may serve as an “oxygen sink” and scavenge oxygen from the molybdenum oxide as it is converted from MoO₃ to MoO₂ during a subsequent anneal treatment. Secondly, the titanium oxide may exist in a rutile crystal structure. Molybdenum oxide may also exist as a distorted rutile crystal structure. Therefore, the titanium oxide may serve to promote the crystallization of the molybdenum oxide during subsequent anneal treatments. This may allow the molybdenum oxide to be crystallized at lower temperatures that will not negatively affect performance of the underlying dielectric materials.

In some embodiments, interface layers including titanium nitride are inserted between the dielectric layer(s) and a second electrode material that includes molybdenum oxide. Without being limited by theory, it is believed that the titanium nitride serves two purposes as an interface layer. Firstly, the titanium nitride may serve as an “oxygen sink” and scavenge oxygen from the molybdenum oxide as it is converted from MoO₃ to MoO₂ during a subsequent anneal treatment. Secondly, the titanium nitride may exist in a cubic crystal structure. Molybdenum oxide may exist as a distorted rutile crystal structure. Therefore, the titanium nitride may serve to promote the crystallization of the molybdenum oxide during subsequent anneal treatments. This may allow the molybdenum oxide to be crystallized at lower temperatures that will not negatively affect performance of the underlying dielectric materials. Finally, the titanium nitride layer may separate the titanium oxide dielectric layer from the molybdenum oxide layer.

In some embodiments, interface layers including zirconium oxide are inserted between the dielectric layer(s) and a second electrode material that includes molybdenum oxide. Without being limited by theory, it is believed that the zirconium oxide serves several purposes as an interface layer. Firstly, the zirconium oxide may serve as an “oxygen sink” and scavenge oxygen from the molybdenum oxide as it is converted from MoO₃ to MoO₂ during a subsequent anneal treatment.

The next step includes forming a second electrode layer, 310, above the second interface layer(s). The second electrode layer may be a metal, metal alloy, conductive metal oxide, conductive metal nitride, conductive metal silicide, or combinations thereof, etc. One class of materials that is of particular interest is the conductive metal oxides. Specific materials of interest comprise molybdenum oxide, tungsten oxide, ruthenium oxide, iridium oxide, chromium oxide, manganese oxide, tin oxide, cobalt oxide, or nickel oxide. Additional candidates for the second electrode material include titanium nitride, nickel, titanium aluminum nitride, platinum, iridium, palladium, cobalt, nickel nitride, tungsten nitride, vanadium nitride, molybdenum nitride, cobalt nitride, ruthenium, ruthenium nitride, nickel oxide, or combinations thereof.

In some embodiments, second electrode, 310, includes multiple layers (not shown). As an example, a thicker titanium nitride layer (e.g. having a thickness between about 1 nm and about 4 nm) may be used as a current conductor and a thinner metal oxide layer (e.g. a molybdenum oxide layer having a thickness between about 0.2 nm and about 4 nm) may be used as a high work function layer. Typically, the molybdenum oxide layer is disposed between the second interface layer, 308, and the titanium nitride layer in this configuration. Other examples of materials for use as the current conductor include titanium nitride, nickel, titanium aluminum nitride, platinum, iridium, palladium, cobalt, nickel nitride, tungsten nitride, vanadium nitride, molybdenum nitride, cobalt nitride, ruthenium, ruthenium nitride, nickel oxide, or combinations thereof. Other examples of metal oxide materials include tungsten oxide, ruthenium oxide, iridium oxide, chromium oxide, manganese oxide, tin oxide, cobalt oxide, or nickel oxide.

The remaining full DRAM device (not shown) would then be manufactured using well known techniques. Optionally, the DRAM capacitor stack may undergo a post metallization anneal (PMA) treatment. Examples of the PDA and PMA treatments described above are further described in U.S. patent application Ser. No. 13/159,842 (now U.S. Pat. No. 8,815,677) filed on Jun. 14, 2011, which is herein incorporated by reference for all purposes.

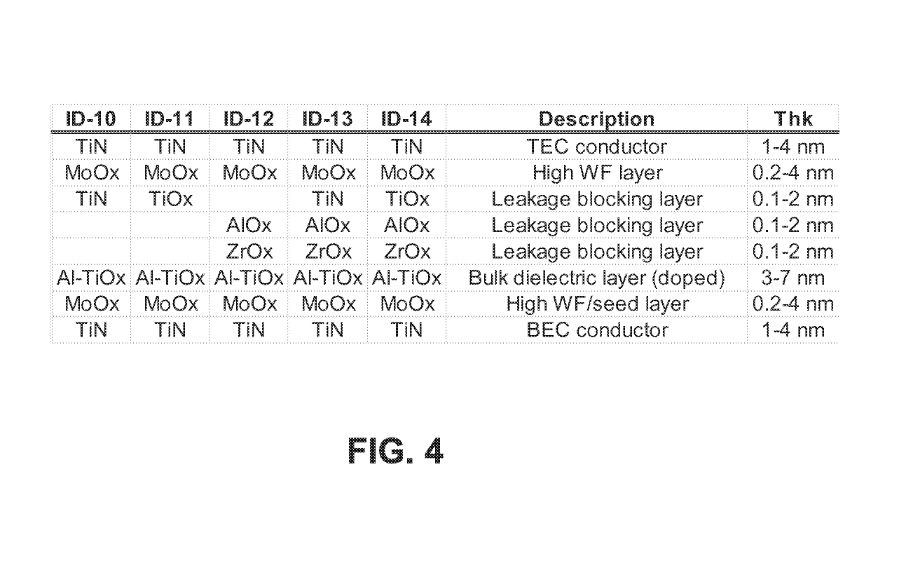

FIG. 4 provides a table of exemplary film stacks in accordance with some embodiments. FIG. 4 lists exemplary film stacks that may correspond to the description and illustration associated with FIG. 3. The five stacks illustrated in FIG. 4 are simple examples and those skilled in the art will understand that other stacks can be envisioned based on the description associated with FIG. 3.

In some embodiments (ID-10), a first electrode layer, 302, includes a titanium nitride layer having a thickness between about 1 nm and about 4 nm and a molybdenum oxide layer having a thickness between about 0.2 nm and about 4 nm. Typically, the molybdenum oxide layer is formed above the titanium nitride layer. A bulk dielectric layer, 306, is formed above the first interface layer and includes a titanium oxide layer having a thickness between about 3 nm and about 7 nm. Typically, the bulk dielectric layer, 306 is doped. Typically, Al is a common dopant used in titanium oxide dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Y, or Zr. A second interface layer, 308, is formed above the bulk dielectric layer and includes a titanium nitride layer having a thickness between about 0.1 nm and about 2 nm. A second electrode layer, 310, is formed above the second interface layer and includes a titanium nitride layer having a thickness between about 1 nm and about 4 nm and a molybdenum oxide layer having a thickness between about 0.2 nm and about 4 nm. Typically, the titanium nitride layer is formed above the molybdenum oxide layer.

In some embodiments (ID-11), a first electrode layer, 302, includes a titanium nitride layer having a thickness between about 1 nm and about 4 nm and a molybdenum oxide layer having a thickness between about 0.2 nm and about 4 nm. Typically, the molybdenum oxide layer is formed above the titanium nitride layer. A bulk dielectric layer, 306, is formed above the first interface layer and includes a titanium oxide layer having a thickness between about 3 nm and about 7 nm. Typically, the bulk dielectric layer, 306 is doped. Typically, Al is a common dopant used in titanium oxide dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Y, or Zr. A second interface layer, 308, is formed above the bulk dielectric layer and includes a titanium oxide layer having a thickness between about 0.1 nm and about 2 nm. A second electrode layer, 310, is formed above the second interface layer and includes a titanium nitride layer having a thickness between about 1 nm and about 4 nm and a molybdenum oxide layer having a thickness between about 0.2 nm and about 4 nm. Typically, the titanium nitride layer is formed above the molybdenum oxide layer.

In some embodiments (ID-12), a first electrode layer, 302, includes a titanium nitride layer having a thickness between about 1 nm and about 4 nm and a molybdenum oxide layer having a thickness between about 0.2 nm and about 4 nm. Typically, the molybdenum oxide layer is formed above the titanium nitride layer. A bulk dielectric layer, 306, is formed above the first interface layer and includes a titanium oxide layer having a thickness between about 3 nm and about 7 nm. Typically, the bulk dielectric layer, 306 is doped. Typically, Al is a common dopant used in titanium oxide dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Y, or Zr. A second interface layer, 304, is formed above the bulk dielectric layer. Second interface layer, 304, is a multilayer stack and includes a zirconium oxide layer, 304-A, having a thickness between about 0.1 nm and about 2 nm and an aluminum oxide layer, 304-B, having a thickness between about 0.1 nm and about 2 nm. A second electrode layer, 310, is formed above the second interface layer(s) and includes a titanium nitride layer having a thickness between about 1 nm and about 4 nm and a molybdenum oxide layer having a thickness between about 0.2 nm and about 4 nm. Typically, the titanium nitride layer is formed above the molybdenum oxide layer.

In some embodiments (ID-13), a first electrode layer, 302, includes a titanium nitride layer having a thickness between about 1 nm and about 4 nm and a molybdenum oxide layer having a thickness between about 0.2 nm and about 4 nm. Typically, the molybdenum oxide layer is formed above the titanium nitride layer. A bulk dielectric layer, 306, is formed above the first interface layer and includes a titanium oxide layer having a thickness between about 3 nm and about 7 nm. Typically, the bulk dielectric layer, 306 is doped. Typically, Al is a common dopant used in titanium oxide dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Y, or Zr. A second interface layer, 304, is formed above the bulk dielectric layer. Second interface layer, 304, is a multilayer stack and includes a zirconium oxide layer, 304-A, having a thickness between about 0.1 nm and about 2 nm, an aluminum oxide layer, 304-B, having a thickness between about 0.1 nm and about 2 nm, and a titanium nitride layer, 304-C, having a thickness between about 0.1 nm and about 2 nm. A second electrode layer, 310, is formed above the second interface layer(s) and includes a titanium nitride layer having a thickness between about 1 nm and about 4 nm and a molybdenum oxide layer having a thickness between about 0.2 nm and about 4 nm. Typically, the titanium nitride layer is formed above the molybdenum oxide layer.

In some embodiments (ID-14), a first electrode layer, 302, includes a titanium nitride layer having a thickness between about 1 nm and about 4 nm and a molybdenum oxide layer having a thickness between about 0.2 nm and about 4 nm. Typically, the molybdenum oxide layer is formed above the titanium nitride layer. A bulk dielectric layer, 306, is formed above the first interface layer and includes a titanium oxide layer having a thickness between about 3 nm and about 7 nm. Typically, the bulk dielectric layer, 306 is doped. Typically, Al is a common dopant used in titanium oxide dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Y, or Zr. A second interface layer, 304, is formed above the bulk dielectric layer. Second interface layer, 304, is a multilayer stack and includes a zirconium oxide layer, 304-A, having a thickness between about 0.1 nm and about 2 nm, an aluminum oxide layer, 304-B, having a thickness between about 0.1 nm and about 2 nm, and a titanium oxide layer, 304-C, having a thickness between about 0.1 nm and about 2 nm. A second electrode layer, 310, is formed above the second interface layer(s) and includes a titanium nitride layer having a thickness between about 1 nm and about 4 nm and a molybdenum oxide layer having a thickness between about 0.2 nm and about 4 nm. Typically, the titanium nitride layer is formed above the molybdenum oxide layer.

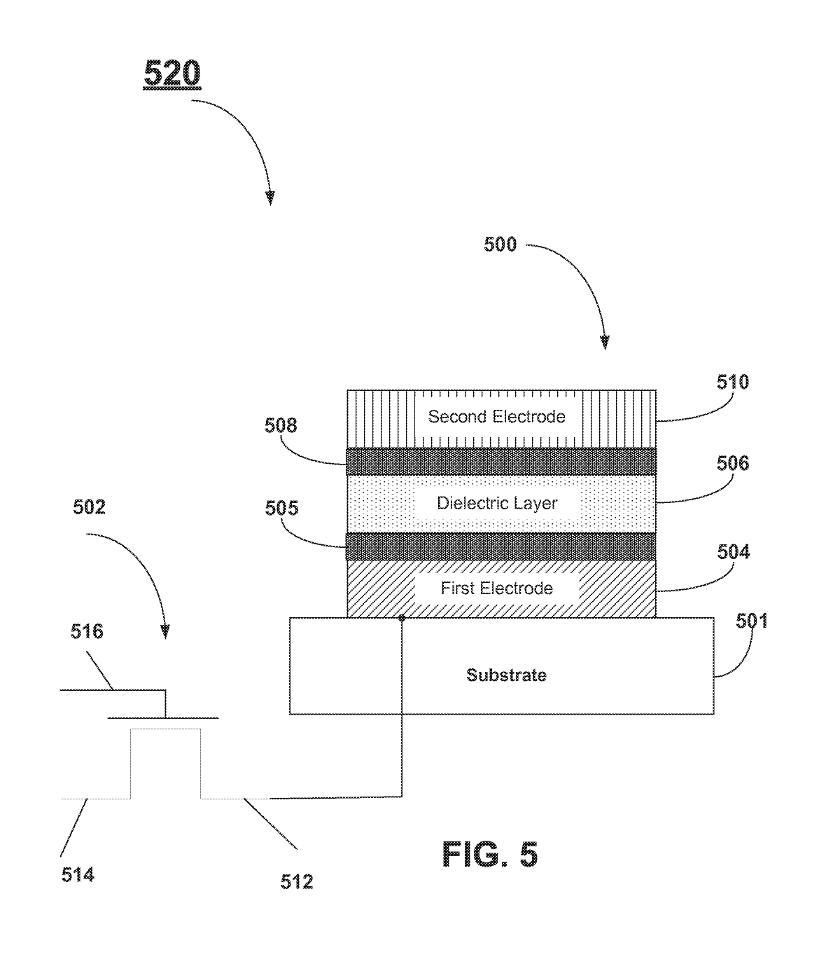

An example of a specific application of some embodiments is in the fabrication of capacitors used in the memory cells in DRAM devices. DRAM memory cells effectively use a capacitor to store charge for a period of time, with the charge being electronically “read” to determine whether a logical “one” or “zero” has been stored in the associated cell. Conventionally, a cell transistor is used to access the cell. The cell transistor is turned “on” in order to store data on each associated capacitor and is otherwise turned “off” to isolate the capacitor and preserve its charge. More complex DRAM cell structures exist, but this basic DRAM structure will be used for illustrating the application of this disclosure to capacitor manufacturing and to DRAM manufacturing. FIG. 5 is used to illustrate one DRAM cell, 520, manufactured using stacks as discussed previously (e.g. FIG. 2 or FIG. 4). The cell, 520, is illustrated schematically to include two principle components, a cell capacitor, 500, and a cell transistor, 502. The cell transistor is usually constituted by a MOS transistor having a gate, 516, source, 512, and drain, 514. The gate is usually connected to a word line and one of the source or drain is connected to a bit line. The cell capacitor has a lower or storage electrode and an upper or plate electrode. The storage electrode is connected to the other of the source or drain and the plate electrode is connected to a reference potential conductor. The cell transistor is, when selected, turned “on” by an active level of the word line to read or write data from or into the cell capacitor via the bit line.

As was described previously, the cell capacitor, 500, comprises a first electrode, 504, formed on substrate, 501. The first electrode, 504, is connected to the source or drain of the cell transistor, 502. For illustrative purposes, the first electrode has been connected to the source, 512, in this example. First electrode layer, 504, comprises one of metals, metal alloys, conductive metal oxides, conductive metal nitrides, conductive metal silicides, etc. One class of materials that is of particular interest is the conductive metal oxides. Specific materials of interest comprise molybdenum oxide, tungsten oxide, ruthenium oxide, iron oxide, iridium oxide, chromium oxide, manganese oxide, tin oxide, cobalt oxide, or nickel oxide. First electrode, 504, may be a single layer or may be a multilayer. For the purposes of illustration, first electrode, 504, will include a multilayer of titanium nitride and molybdenum oxide in this example. As discussed previously, first electrode, 504, may be subjected to an anneal before the formation of the dielectric layer. First interface layer, 505, is formed above the first electrode. As mentioned previously, first interface dielectric layer, 505, may be a single layer or may be a multilayer. In some embodiments, first interface layer is omitted (e.g. stacks illustrated in FIG. 4). Advantageously, the thickness of each of the interface layers is less than 2.0 nm. Examples of materials that would make suitable first interface layers include titanium nitride, titanium oxide, or combinations thereof. Bulk dielectric layer, 506, is formed on top of the first interface dielectric layer. Examples of suitable dielectric materials comprise Al₂O₃, HfO₂, HfSiOₓ, ZrO₂, Ta₂O₅, TiO₂, Nb₂O₅, SrTiO₃ (STO), BaSrTiOₓ (BST), PbZrTiOₓ (PZT), or doped versions of the same. These bulk dielectric materials may be formed as a single layer or may be formed as a hybrid or nanolaminate structure. In some embodiments, a specific dielectric material of interest is doped TiO₂. Typically, Al is a common dopant used in TiO₂ dielectrics to reduce the leakage current although many other dopants are also commonly used. Potential dopants as described previously comprise one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Y, or Zr. In some embodiments, a specific dielectric material of interest is doped ZrO₂. Typically, Al is a common dopant used in ZrO₂ dielectrics to reduce the leakage current although many other dopants are also commonly used. Other dopants may include one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Ti, or Y. Typically, the bulk dielectric layer is then subjected to a PDA treatment. Second interface dielectric layer, 308, is formed on the bulk dielectric layer. Second interface layer, 508, is formed above the bulk dielectric. As mentioned previously, second interface layer, 508, may be a single layer or may be a multilayer. Advantageously, the thickness of each of the interface layers is less than 2.0 nm. Examples of materials that would make suitable first interface layers include aluminum oxide, titanium nitride, titanium oxide, zirconium oxide, or combinations thereof. The next step includes forming a second electrode layer, 510, above the second interface layer. In some embodiments, second electrode layer, 510, includes multiple layers (not shown). As an example, a thicker titanium nitride layer (e.g. having a thickness between about 1 nm and about 4 nm) may be used as a current conductor and a thinner metal oxide layer (e.g. a molybdenum oxide layer having a thickness between about 0.2 nm and about 4 nm) may be used as a high work function layer. Typically, the molybdenum oxide layer is disposed between the second interface layer, 508, and the titanium nitride layer in this configuration. Other examples of materials for use as the current conductor include titanium nitride, nickel, titanium aluminum nitride, platinum, iridium, palladium, cobalt, nickel nitride, tungsten nitride, vanadium nitride, molybdenum nitride, cobalt nitride, ruthenium, ruthenium nitride, nickel oxide, or combinations thereof. Other examples of metal oxide materials include tungsten oxide, ruthenium oxide, iridium oxide, chromium oxide, manganese oxide, tin oxide, cobalt oxide, or nickel oxide. The remaining full DRAM device (not shown) would then be manufactured using well known techniques. Optionally, the DRAM capacitor stack may undergo a PMA treatment as discussed previously. This completes the formation of the capacitor stack.

Those skilled in the art will understand that a DRAM cell, 520, may be formed using any one of the stacks as illustrated in FIG. 2, wherein the bulk dielectric layer includes zirconium oxide and/or doped zirconium oxide. As discussed previously, those skilled in the art will understand that a DRAM cell, 520, may be formed using other stacks as discussed with respect to FIG. 1.

Those skilled in the art will understand that a DRAM cell, 520, may be formed using any one of the stacks as illustrated in FIG. 4, wherein the bulk dielectric layer includes titanium oxide and/or doped titanium oxide. As discussed previously, those skilled in the art will understand that a DRAM cell, 520, may be formed using other stacks as discussed with respect to FIG. 3.

Although the foregoing examples have been described in some detail for purposes of clarity of understanding, the invention is not limited to the details provided. There are many alternative ways of implementing the invention. The disclosed examples are illustrative and not restrictive.

1. A capacitor stack comprising:
a first electrode layer formed above a surface of a substrate;
a first interface dielectric layer formed above the first electrode layer;
a bulk dielectric layer formed above the first interface layer;
a second interface layer formed above the bulk dielectric layer,
wherein the second interface layer is a multilayered stack comprising a first layer and a second layer,
wherein the first layer of the multilayered stack comprises a first oxide different from a material of the bulk dielectric layer,
wherein the second layer of the multilayered stack comprises a second oxide different from the first oxide and different from the material of the bulk dielectric layer; and
a second electrode formed above the second interface layer such that the second interface layer is disposed between the bulk dielectric layer and the second electrode,
wherein the second electrode comprises molybdenum oxide.

2. The capacitor stack of claim 1, wherein a thickness of each of the first interface layer and the second interface layer is between 0.1 nm and 2 nm.

3. The capacitor stack of claim 1, wherein the bulk dielectric layer comprises TiO₂ and a dopant.

4. The capacitor stack of claim wherein the dopant of the bulk dielectric layer comprises one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Y, or Zr.

5. The capacitor stack of claim 1, wherein the bulk dielectric layer comprises ZrO₂ and a dopant.

6. The capacitor stack of claim wherein the dopant of the bulk dielectric layer comprises one or more of Al, As, Bi, Br, C, Ce, Cl, Co, Er, F, Ga, Gd, Ge, Hf, I, In, La, Lu, Mg, Mn, Nd, P, Pr, S, Sb, Sc, Se, Sn, Sr, Te, Ti, or Y.

7. The capacitor stack of claim 1, wherein the second electrode further comprises titanium nitride.

8-20. (canceled)

21. The capacitor stack of claim 7, wherein a layer of the second electrode comprising molybdenum oxide is disposed between a layer of the second electrode comprising titanium nitride and the second interface layer.

22. The capacitor stack of claim 21, wherein the layer of the second electrode comprising molybdenum oxide has a thickness of between 0.2 nm and 4 nm.

23. The capacitor stack of claim 21, wherein the layer of the second electrode comprising titanium nitride has a thickness of between 1 nm and 4 nm.

24. The capacitor stack of claim 1, wherein the first oxide of the first layer of the multilayered stack is zirconium oxide and wherein the second oxide of the second layer of the multilayered stack is aluminum oxide.

25. The capacitor stack of claim 1, wherein the first layer of the multilayered stack is disposed between the bulk dielectric layer and the second layer of the multilayered stack.

26. The capacitor stack of claim 25, wherein the first layer of the multilayered stack is directly interfaces the bulk dielectric layer.

27. The capacitor stack of claim 25, wherein the bulk dielectric layer comprises titanium oxide.

28. The capacitor stack of claim 27, wherein the bulk dielectric layer is doped with aluminum.

29. The capacitor stack of claim 24, wherein the first layer of the multilayered stack has a thickness of between 0.1 nm and 2 nm.

30. The capacitor stack of claim 24, wherein the second layer of the multilayered stack has a thickness of between 0.1 nm and 2 nm.

31. The capacitor stack of claim 1, wherein the multilayered stack further comprises a third layer comprises titanium nitride.

32. The capacitor stack of claim 31, wherein the third layer is disposed between the second electrode and a combination of the first layer and the second layer of the multilayered stack.

33. The capacitor stack of claim 31, wherein the third layer directly interfaces the second electrode.
